(19) United States
(12) Patent Application Publication
(10) Pub. No.: US 2013/0057288 A1
(43) Pub. Date: Mar. 7, 2013

(54) MAGNETIC MEASUREMENT SYSTEM AND METHOD FOR MEASURING MAGNETIC FIELD

(71) Applicants: Kuniomi OGATA, Tokorozawa (JP); Ryuzo Kawabata, Higashiyamato (JP); Akihiro Kandori, Tokyo (JP); Katsunori Kojima, Oyamazaki (JP); Ryo Nagai, Oyamazaki (JP)

(72) Inventors: Kuniomi OGATA, Tokorozawa (JP); Ryuzo Kawabata, Higashiyamato (JP); Akihiro Kandori, Tokyo (JP); Katsunori Kojima, Oyamazaki (JP); Ryo Nagai, Oyamazaki (JP)

(73) Assignee: HITACHI, LTD.

(21) Appl. No.: 13/559,402

(22) Filed: Jul. 26, 2012

(30) Foreign Application Priority Data
Sep. 6, 2011 (JP) 2011-193613

(51) Int. Cl. G01R 33/02; G01N 27/416

(52) U.S. Cl. 324/426

(57) ABSTRACT

In a magnetic measurement system for a battery, a magnetic signal generated by electric currents in the battery for charging and discharging can be accurately measured without saturating the output of a magnetic sensor even in an environment having strong magnetic noise, and electric current distribution in the lithium-ion battery is visualized. Generating a antiphase magnetic field having an antiphase magnetic field to a magnetic field measured by each magnetic sensor into the cancel coil disposed around each the magnetic sensor before charging and discharging; thereafter, reducing magnetic noise by subtracting the magnetic data recorded before charging and discharging (the correction-magnetic field data) from the magnetic data for charging and discharging; and accurately measuring the magnetic signal generated from the lithium-ion battery for charging and discharging are included.

### CLAIM OF PRIORITY

The present application claims priority from Japanese patent application JP 2011-193613 filed on Sep. 6, 2011, the content of which is hereby incorporated by reference into this application.

### FIELD OF THE INVENTION

The present invention relates to a magnetic measurement system for batteries. The invention more particularly relates to a system and method using magnetic sensors for measuring a magnetic field generated from a battery, such as a lithium-ion battery, during charging and discharging.

### BACKGROUND OF THE INVENTION

Recently, much attention has been attracted to electricity storage technologies including secondary batteries. For example, developments of an electricity storage system storing renewable energy such as solar power generation and wind power generation which do not generate CO₂ and a storage battery for an electric vehicle, a hybrid vehicle, and a plug-in hybrid vehicle are advanced by various organizations.

As the secondary batteries which attract much attention as described above, nickel cadmium batteries and nickel metal hydride batteries have been widely used for digital cameras and hybrid vehicles. Recently, lithium-ion batteries which have higher electric capacity have been developed and are becoming popular. The lithium-ion battery can obtain high voltage (3.7 V) and has high energy density because the battery uses a nonaqueous electrolyte. The lithium-ion battery is useful for applications ranging from a battery for mobile devices such as a cellular phone and a notebook personal computer to a battery for the electric vehicle and the hybrid vehicle, because the lithium-ion battery can realize high voltage even though the battery is light weight and of small size. In addition, further increase in the demand for the battery is expected in the future.

With the increase in the demand for the lithium-ion battery, enhancement of performance of the lithium-ion battery is an important problem. By enhancing the performance of the lithium-ion battery, reduction in size of a device using the battery and a long operating time of the device are possible. Therefore, in order to enhance the battery performance, research and development of constituent materials of the battery is actively pursued. With wider popularity of the lithium-ion battery, quality is also one of the important problems. Battery voltage and battery capacity of the lithium-ion battery is decreased with long time use. This phenomenon is referred to as capacity degradation of a battery. When the capacity degradation occurs, operation time of a device using the battery becomes shorter or the device cannot be used suddenly.

Therefore, for evaluating the performance and the quality of the lithium-ion battery and supporting a battery design, measurement of battery voltage after repeating charge and discharge of the battery and measurement of an alternating-current impedance (internal resistance) are performed (for example, Kazuhiko Takeno and Remi Shirota: “Capacity Degradation Characteristics of Lithium-ion Battery for Mobile Handset,” NTT DoCoMo Technical Journal, Vol. 13, No. 4, pp. 62-65, 2006).

Although not for the lithium-ion battery, as an apparatus for evaluating performance of a fuel cell battery in detail, an apparatus which measures a magnetic field generated from the battery, calculates electric current distribution in the battery from the measured magnetic signal, and visualizes the electric current distribution has been developed (for example, Japanese Unexamined Patent Application Publication (Translation of PCT Application) No. 2004-500689, Japanese Unexamined Patent Application Publication No. 2005-183039, and Japanese Unexamined Patent Application Publication No. 2006-216390).

For example, Japanese Unexamined Patent Application Publication (Translation of PCT Application) No. 2004-500689 (Patent Document 1) provides a method for determining electric current density distribution in a fuel cell battery, enabling determination of the electric current density distribution in the fuel cell battery across a cross section of the battery in any position of the battery. Patent Document 1 describes that, in the method for determining the electric current density distribution Jx, Jy, Jz (x, y, z) in the fuel cell battery, the electric current density distribution is determined from a magnetic field (B) generated by the electric current in the fuel cell battery and surrounding the battery. Patent Document 1 describes that, by this characteristic, the method is advantageous in that does not require a change in the fuel cell battery itself, and moreover, the fuel cell battery is not required to be fixed and high measurement accuracy can be obtained based on high resolution while the cost per measurement process is also reduced.

Japanese Unexamined Patent Application Publication No. 2005-183039 (Patent Document 2) describes a method for measuring electric current distribution of a stacked type fuel cell battery which stacks fuel cells in which an air electrode and a fuel electrode are joined to one surface of an electrolyte and the other surface of the electrolyte respectively, and the joined body is clamped with a separator having a gas channel. The method includes: disposing a magnetic sensor at a circumference part perpendicular to a thickness direction in which fuel cells of a fuel cell stack are stacked; measuring a magnetic field generated at the time of electricity flowing through the fuel cell stack along the thickness direction using the magnetic sensor; and measuring the electric current distribution of the fuel cell stack from the measured magnetic field. Patent Document 2 describes that, by this characteristic, the magnetic field generated by electric current flow along a thickness direction of a fuel cell stack is measured and the electric current distribution of the fuel cell stack is obtained from the measured magnetic field.

Japanese Unexamined Patent Application Publication No. 2006-216390 (Patent Document 3) describes a method for measuring electric current distribution of a stacked type fuel cell battery which stacks fuel cells in which an air electrode and a fuel electrode are joined to one surface of an electrolyte and the other surface of the electrolyte respectively, and the joined body is clamped with a separator having a gas channel, and disposes a collector which takes out electric power at its edge in a direction perpendicular to the thickness direction. The method includes: disposing a magnetic sensor at the edge of the fuel cell stack in the thickens direction, measuring a magnetic field generated at the time of electricity flowing through the collector using the magnetic sensor; and measuring the electric current distribution of the fuel cell stack from the measured magnetic field. Patent Document 3 describes that, by this characteristic, a magnetic field generated by electric current flow through the collector disposed at the edge of the fuel cell stack is measured and the electric current distribution through the fuel cell stack can be obtained from the measured magnetic field.

### SUMMARY OF THE INVENTION

According to related arts, voltage and internal resistance of a lithium-ion battery for charging and discharging have been obtained by measuring the voltage across the terminals of the battery. Therefore, although evaluation for performance and quality of a whole battery has been possible, evaluation of a local part in the battery has been difficult. Consequently, in order to evaluate the performance and the quality of the lithium-ion battery in detail, a method which can evaluate the performance and the quality in higher spatial resolution has been required.

When the magnetic measurements of the fuel cell battery described in Patent. Documents 1 to 3 are applied to the lithium-ion battery during charging and discharging, a problem with magnetic noise arises. When the magnetic measurement of the lithium-ion battery during charging and discharging is performed, a charge and discharge device is operated around the lithium-ion battery. A magnetic field generated from circuits and a power supply constituting the charge and discharge device significantly affects the measured data. Also, ferromagnetic materials may be used for materials constituting a battery such as nickel used for terminals of electrodes of the lithium-ion battery and cobalt used for a positive-electrode material, and as a result, a magnetic field steadily generated from the battery itself also has significant effect. When intensity of these magnetic fields becomes high, output of the magnetic sensor is saturated. As a result, the magnetic field generated by electric current in the battery cannot be recorded. The intensity of the magnetic field is sharply changed depending on a distance from a magnetic field source which generates the magnetic field to the magnetic sensor. Consequently, difference in the magnetic field generated by the device and the battery becomes high depending on a measurement position. Therefore, for each magnetic sensor, it is necessary that the magnetic sensor is stably operated without saturating its output, and that the magnetic field generated from the surrounding device and the magnetic field steadily generated from the materials constituting the lithium-ion battery are reduced.

Patent Document 1 describes that, in measurement preceding the specific measurement, the earth's magnetic field is measured and the value of the earth's magnetic field is subtracted from the specific measurement. Patent Document 2 describes that, although an error about ±0.3×10⁻⁴ T (0.3 G) is generated by the earth's magnetism, the earth's magnetism can be corrected by disposing a plurality of magnetic sensors and measurement having higher accuracy can be performed, and Patent Document 3 also has similar description. However, at the time of magnetic measurement of the lithium-ion battery during charging and discharging, the magnetic sensor is saturated depending on the intensity of the magnetic field generated from the surrounding device and the lithium-ion battery, and thereby, the measurement by the magnetic sensor becomes difficult.

An object of the present invention is to accurately measure magnetic signals generated by electric current in the lithium-ion battery during charging and discharging without saturating the output of the magnetic sensor even in an environment having strong magnetic noise, and to visualize electric current distribution in the lithium-ion battery.

In order to address the problem described above, in an embodiment of the present invention, a magnetic measurement system for measuring a magnetic field generated from a lithium-ion battery includes: an electric current/voltage applying portion which applies electric current or voltage, or which alternately applies electric current and voltage through terminals of the lithium-ion battery; a magnetic sensor which measures the resulting magnetic field generated from the lithium-ion battery; a cancel coil which is disposed so as to surround the magnetic sensor and cancels magnetic noise detected by the magnetic sensor; a recording portion which records a magnetic field detected by the magnetic sensor when no electric current or voltage is applied to terminals of the lithium-ion battery as a correction-magnetic field; differential process portion which calculates a difference between a magnetic field generated from the lithium-ion battery when electric current or voltage is applied, or electric current and voltage are alternately applied, and the correction-magnetic field recorded by the recording portion; and an electric current distribution calculation portion which calculates electric current distribution in the lithium-ion battery from the difference calculated by the differential process portion.

In other words, a technique of the present invention includes generating a magnetic field having an antiphase relationship to an ambient magnetic field measured by each magnetic sensor in the cancel coil disposed around each magnetic sensor before charge and/or discharge; thereafter, further reducing magnetic noise by subtracting the magnetic field data recorded before charge and/or discharge (the correction-magnetic field data) from the magnetic field data during charging and/or discharging; and accurately measuring the magnetic signal generated from the lithium-ion battery during charging and/or discharging. In addition, the present invention includes visualizing the electric current distribution in the battery from the accurately measured magnetic signal based on a method of current-arrow map.

Other embodiments will be clarified in this specification.

According to the present invention, the magnetic signal generated by electric current in the battery when charging and when discharging is accurately measured without saturating the output of the magnetic sensor even in an environment having strong magnetic noise, and the electric current distribution in the lithium-ion battery can be visualized.

### BRIEF DESCRIPTION OF DRAWINGS

FIG. 1 is a view illustrating one example of a magnetic measurement system for a battery according to the present invention;

FIG. 2 is a view illustrating one example of an array of magnetic sensors used in the magnetic measurement system for the battery according to the present invention, and an arrangement of the magnetic sensors for use with a laminated lithium-ion battery;

FIGS. 3A and 3B are flowcharts illustrating procedures for measurement according to the present invention;

FIGS. 4A and 4B are flowcharts illustrating procedures for analysis processes according to a first and a second embodiment of methods of the present invention;

FIG. 5 is a view illustrating magnetic field distribution of the lithium-ion battery determined according to the first embodiment just after a start of charge;

FIG. 6 is a view illustrating electric current distribution of the lithium-ion battery determined according to the first embodiment just after the start of charge;

FIG. 7 is a view illustrating magnetic field distribution of the lithium-ion battery determined according to the first embodiment after 15 minutes from the start of charge;

FIG. 8 is a view illustrating electric-current distribution of the lithium-ion battery determined according to the first embodiment after 15 minutes from the start of charge;

FIG. 9 is a view illustrating magnetic field distribution of the lithium-ion battery just after the start of charge when magnetic noise is not canceled;

FIG. 10 is a view illustrating electric current distribution of the lithium-ion battery just after the start of charge when the magnetic noise is not canceled;

FIG. 11 is a view illustrating magnetic field distribution of the lithium-ion battery determined according to the second embodiment just after a start of discharge;

FIG. 12 is a view illustrating electric current distribution of the lithium-ion battery determined according to the second embodiment just after the start of discharge;

FIG. 13 is a view illustrating magnetic field distribution of the lithium-ion battery determined according to the second embodiment after 20 minutes from the start of discharge;

FIG. 14 is a view illustrating electric current distribution of the lithium-ion battery determined according to the second embodiment after 20 minutes from the start of discharge;

FIG. 15 is a view illustrating magnetic field distribution of a lithium-ion battery determined according to the second embodiment just after the start of discharge when magnetic noise is not canceled;

FIG. 16 is a view illustrating electric current distribution of a lithium-ion battery just after the start of discharge when the magnetic noise is not canceled;

FIG. 17 is a flowchart illustrating a procedure for an analysis process according to a third embodiment of a method according to the present invention;

FIG. 18 is a view illustrating distribution of time variation in a magnetic field of the lithium-ion battery determined according to the third embodiment after 15 minutes from a start of charge using a magnetic field just after the start of charge as a reference;

FIG. 19 is a view illustrating distribution of time variation in electric current of the lithium-ion battery determined according to the third embodiment after 15 minutes from the start of charge using a magnetic field just after the start of charge as the reference;

FIG. 20 is a flowchart illustrating a procedure for an analysis process according to a fourth embodiment of a method according to the present invention;

FIG. 21 is a view illustrating distribution of time variation in a magnetic field of the lithium-ion battery determined according to the fourth embodiment after 20 minutes from the start of discharge, using a magnetic field just after the start of discharge as a reference;

FIG. 22 is a view illustrating distribution of time variation in electric current of the lithium-ion battery determined according to the fourth embodiment after 20 minutes from the start of discharge, using a magnetic field just after the start of discharge as the reference;

FIG. 23 is a view illustrating a magnetic measurement system according to an embodiment utilizing a unit in which several magnetic sensors are disposed; and

FIG. 24 is a view illustrating a magnetic measurement system according to a variation utilizing two units of the type shown in FIG. 23.

### DETAILED DESCRIPTION OF THE PREFERRED EMBODIMENTS

Hereinafter, embodiments for implementing the present invention (hereinafter, referred to as “embodiments”) are described in detail with reference to the drawings.

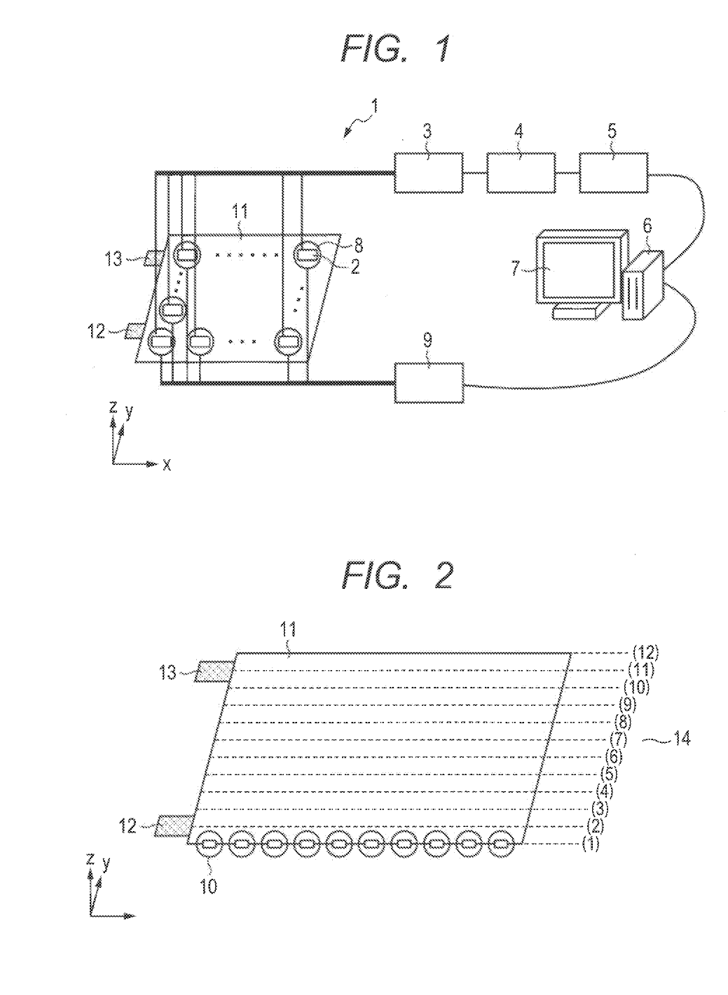

FIG. 1 is a schematic view illustrating whole constitution of a magnetic measurement system for a battery according to this embodiment. As illustrated in FIG. 1, when a lithium-ion battery 11 is disposed in a plane determined by x-y axes, constituents of the magnetic measurement system 1 of the lithium-ion battery are as follows: a plurality of magnetic sensors 2 for measuring magnetic signals B_{z} in a direction perpendicular to an electrode surface of the lithium-ion battery 11 (a z direction); a driving circuit 3 driving the magnetic sensors; an amplifier filter unit 4 for amplifying and filtering the output from the driving circuit 3; an A/D converter 5 for converting the output from the amplifier filter unit 4 into digital signals; a controlling and computing device 6 for collecting the output signals from the A/D converter 5 as data, performing an analysis process of the collected data (hereinafter referred to as “magnetic field data”), and controlling each part of the battery magnetic measurement system 1; and a display device 7 for displaying the analyzed data which is analyzed by the controlling and computing device 6. Around the magnetic sensors 2, cancel coils 8 which generate antiphase magnetic fields for canceling magnetic noise in a z direction measured by each magnetic sensor 2 are disposed

Magnitude of a respective electric current applied to each cancel coil 8 is determined by the controlling and computing device 6. Digital signals generating this electric current value are outputted from the controlling and computing device 6 and are converted into analog signals by a D/A converter 9. Adequate electric current is applied to the cancel coils 8 by the analog signals converted by the D/A converter 9, and a magnetic field is generated by the cancel coils 8.

To the battery magnetic measurement system 1 of this embodiment, magnetic sensors for measuring a magnetic signal Bₓ in an x direction in parallel with the electrode surface of the lithium-ion battery and a magnetic signal B_{y} in a y direction perpendicular to the x direction are also applicable. For such purposes cancel coils 8 are disposed so as to generate a magnetic field for cancelling the magnetic noise in the x direction and the magnetic noise in the y direction.

The magnetic measurement system 1 of this embodiment has characteristics of canceling the ambient magnetic field by the cancel coil 8 and cancelling the residual magnetic field not cancelled by the cancel coil by the controlling and computing device 6 using magnetic field data recorded before the charging and/or the discharging (correction-magnetic field data). Therefore, constitution and operation of the magnetic measurement system of the present invention is adequately applicable for any lithium-ion battery regardless of the battery shape (for example, a rectangular shape, a cylindrical shape, or laminated shape). In this embodiment, particularly, the magnetic measurement system 1 having constitution for measuring a magnetic field generated from the laminated lithium-ion battery is described.

As to the magnetic sensor 2 of the magnetic measurement system 1 of this embodiment, the constitution and the operation of the magnetic measurement system of the present invention can be adequately applicable for any magnetic sensor, for example, a hall element, a magnetic impedance (MI) sensor, a magnetic resistance (MR) sensor, and a flux gate. In this embodiment, particularly, the magnetic measurement system 1 using the MR sensor is described.

FIG. 2 is a view illustrating one example of an array of MR sensors 10 used in the magnetic measurement system 1 as applied to the laminated lithium-ion battery 11. The MR sensors are disposed so as to measure the magnetic field component B_{z} in the z direction perpendicular to the electrode plane generated from the laminated lithium-ion battery 11. The MR sensors 10 are disposed in the x direction at even intervals, and the magnetic field is measured in the entire plane of the lithium-ion battery 11 with sliding the sensors along the y direction, such as by hand. In this example, 12 lines of measurement positions 14 disposed along the x direction are provided as illustrated from (1) to (12). After completion of the measurement at (1), measurement at (2) is performed, and then measurement at (3) is performed. These measurements are repeatedly performed to (12).

Terminal parts (a positive terminal 12 and a negative terminal 13) for inputting and outputting electric power to and from the battery are connected to the electrodes of the lithium-ion battery 11. Charge and discharge of the lithium-ion battery are performed by applying electric current, voltage, or electric current and voltage having predetermined magnitude for predetermined time via these terminal parts.

In order to accurately measure a magnetic field from the electrode surface of the lithium-ion battery, arrangement of the magnetic sensors disposed in the x direction and the y direction at even intervals to cover the entire electrode surface of the lithium-ion battery is applicable to the magnetic measurement system 1 according to this embodiment.

In this embodiment, as one example, measurement was performed for 12 positions ((1) to (12) in the view) of the measurement positions 14 in total (total measured points: 120 points) with sliding the MR sensors having an interval of 0.02 m along the y direction by 0.01 m by hand.

In addition, in this embodiment, magnetic signals from the lithium-ion battery at each measurement position were recorded for 10 seconds at 1 kHz sampling frequency, and the data was stored on a hard disk (not illustrated) in the controlling and computing device 6. At the time of recording the magnetic signals from the lithium-ion battery, a high-pass filter and a low-pass filter were set to 0.1 and 30 Hz, respectively.

Electric current for charging was set to 10 A, and the magnetic signals before charge, just after the start of charge, and after 15 minutes from the start of charge were measured. After completion of the measurement for charging, magnetic signal for discharging was measured. Electric current for discharging was also set to 10 A, and magnetic signals just after the start of discharge and after 20 minutes from the start of discharge were measured. Here, before the magnetic measurements of the lithium-ion battery for charging and discharging, a magnetic field which is antiphase to the ambient magnetic field measured by the magnetic sensors is generated by applying electric current to the cancel coils 8 for canceling the ambient magnetic field measured by the magnetic sensors in order to make output of the magnetic sensors near zero.

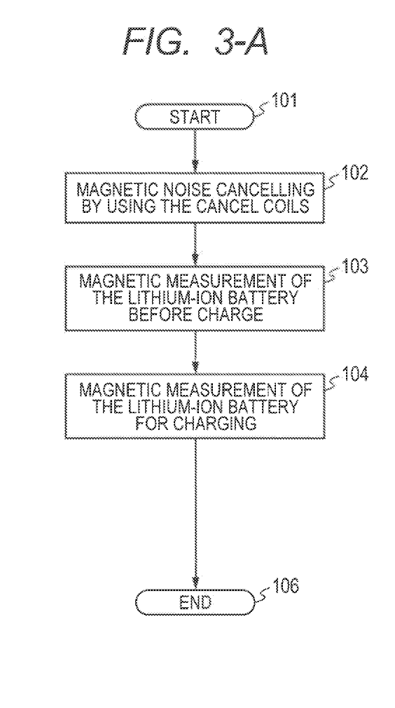

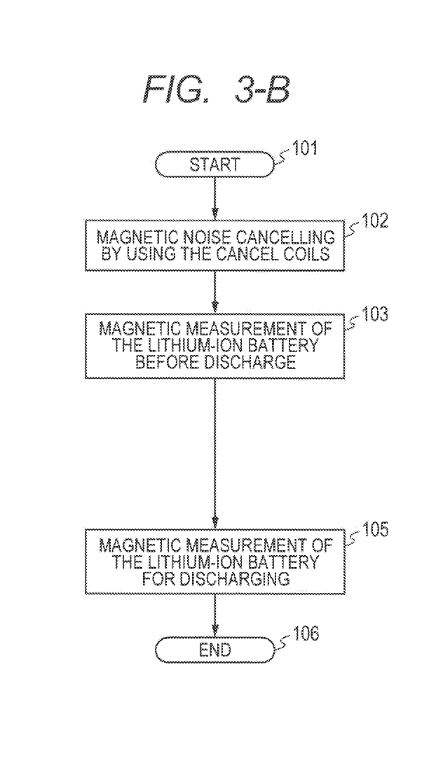

Flow of the measurement processes in this embodiment is illustrated in FIGS. 3A and 3B. First, when the measurement is started (101), magnetic noise measured by the MR sensors is firstly canceled using the cancel coils (102). Subsequently, a magnetic signal before a start of charge and discharge (correction-magnetic field signals) is recorded (103). Thereafter, a magnetic signal for charging is recorded (104), or a magnetic signal for discharging is recorded (105), and then the measurement terminates.

### First Embodiment of Method

As the first embodiment of a method according to the invention, a procedure in which environment noise of a magnetic signal from a lithium-ion battery recorded when charging is removed by using a magnetic signal measured before a start of charging (a correction-magnetic field signal) and electric current distribution in the lithium-ion battery is accurately displayed is described below.

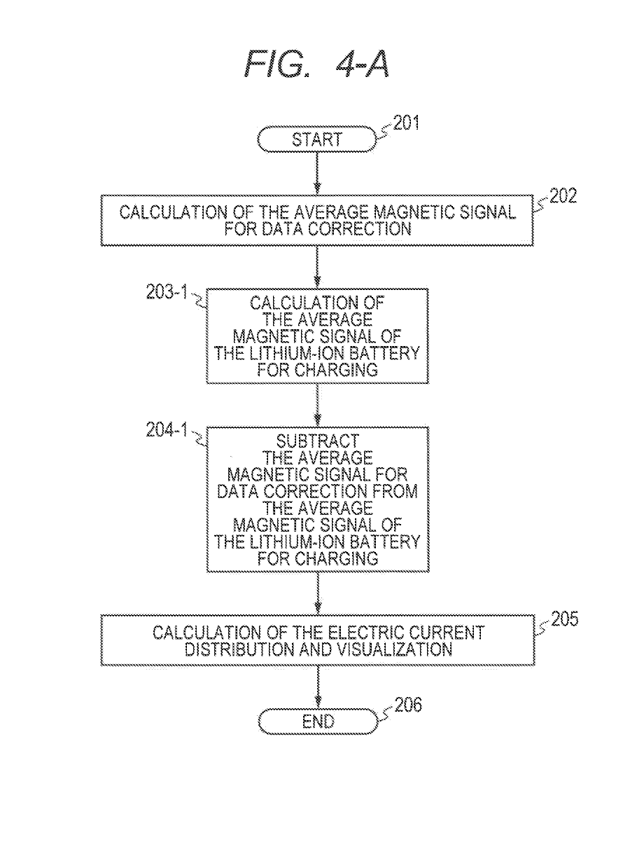

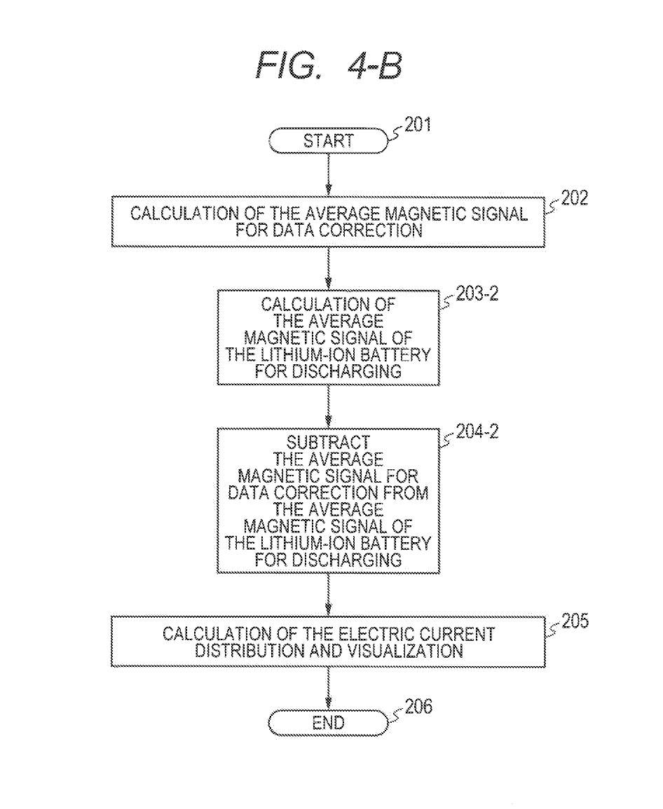

A flow chart of the processes of the analysis procedure in this embodiment is illustrated in FIG. 4A. In the following description, a step number corresponding to each process of procedure is represented in parentheses.

First, with ambient noise cancelled by each cancel coil 8, the procedure is started (201), and for each magnetic sensor 2, an average magnetic signal for correction is calculated from a magnetic signal recorded before charge (a correction-magnetic field signal) (202). Subsequently, for each magnetic sensor an average magnetic signal for charging is calculated (203-1); a difference is calculated by subtracting the average magnetic signal for data correction from the average magnetic signal for charging (204-1); and electric current distribution is calculated and visualized (205). Details of each process are described below.

In the process 202, an arithmetic average of the magnetic signal recorded before charge (a correction-magnetic field signal) is calculated and the average is used for data correction.

In the process 203-1, in order to improve an SN ratio of the magnetic signal for charging, an average of the magnetic signal for charging is calculated.

In the process 204-1, the difference is calculated by subtracting the average magnetic signal for data correction calculated in the process 202 from the averaging magnetic signal for charging calculated in the process 203-1.

In the process 205, the method of current-arrow map was used for calculating electric current distribution from the magnetic signal of the lithium-ion battery. The current-arrow map is a view in which magnetic fields in x and y directions are analytically calculated from the magnetic field in the z direction (B_{z}) and an effective magnetic field which is a combination of these magnetic fields is projected on a measurement plane as a pseudo-electric current vector and displayed. Therefore, the method of current-arrow map can reconstitute the same number of electric current vectors as the number of measurement points, and displays a size of the electric current vector as contour lines and a length of an arrow, and a direction of the electric current vector as a direction of the arrow.

Each of an x component (I_{x, i}) and a y component (I_{y, i}) of an electric current vector (Iᵢ) at an i-th position (i=1, 2, . . . , 120) obtained from the method of current-arrow map is derived from the following formulae using B_{z, i}.

I_{x, i}=dB_{z, i}/dy Formula (1)

I_{y, i}=−dB_{z, i}/dx Formula (2)

A size of the electric current vector (|Iᵢ|)is calculated by the following formula.

|Iⁱ|=√(I_{x, i}) ²+(I_{y, i})²) Formula (3)

When a magnetic field in the x direction (Bₓ) and a magnetic field in the y direction (B_{y}) are measured, each of the x component (I_{x, i}) and the y component (I_{y, i}) of the electric current vector (Iᵢ) at the i-th position obtained from the method of current-arrow map is derived from the following formulae using B_{x, i} and B_{y, i}.

I_{x, i}=B_{y, i} Formula (4)

I_{y, i}=−B_{x, i} Formula (5)

A size of the electric current vector (|Iᵢ|) is calculated in a similar manner to Formula (3).

Processes of the first embodiment are performed though the procedure from the process 201 to 205 described above at each measurement time (i.e., just after the start of charging and 15 minutes from the start of charging). Optionally, step 202 may be performed once and the results used in step 204-1 for each measurement time. Next, application of the first embodiment for a magnetic signal of the laminated lithium-ion battery and effectiveness thereof are described.

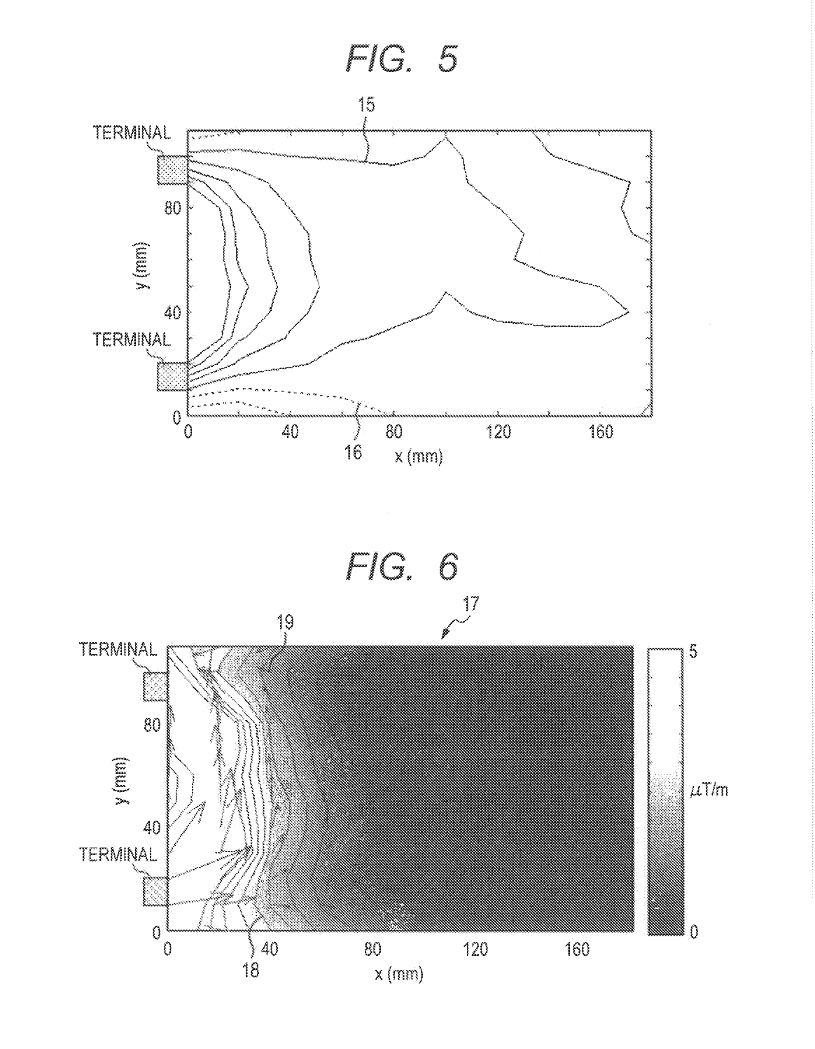

FIG. 5 is a view illustrating magnetic field distribution of the lithium-ion battery just after a start of charge displayed by contour lines. Solid lines 15 and dotted lines 16 in FIG. 5 represent contour lines corresponding to a positive magnetic field and a negative magnetic field of the lithium-ion battery for charging, respectively. From FIG. 5, it can be seen that the density of the contour lines at the far left is high.

FIG. 6 illustrates an electric current distribution diagram calculated from the magnetic field distribution of FIG. 5 based on the method of current-arrow map. A gray-scale map 17 of FIG. 6 illustrates distribution of electric current intensity. A region having low electric current intensity is illustrated in black and a region having high electric current intensity is illustrated in white. Solid lines 18 in FIG. 6 illustrate contour lines corresponding to the electric current intensity. Lengths of arrows 19 in FIG. 6 are corresponding to the electric current intensity and directions of the arrows 19 are corresponding to directions of electric current vectors. From FIG. 6, the electric current intensity of a terminal part at the far left is high, and the directions of the electric current vectors is right in a lower left region and is left in an upper left region.

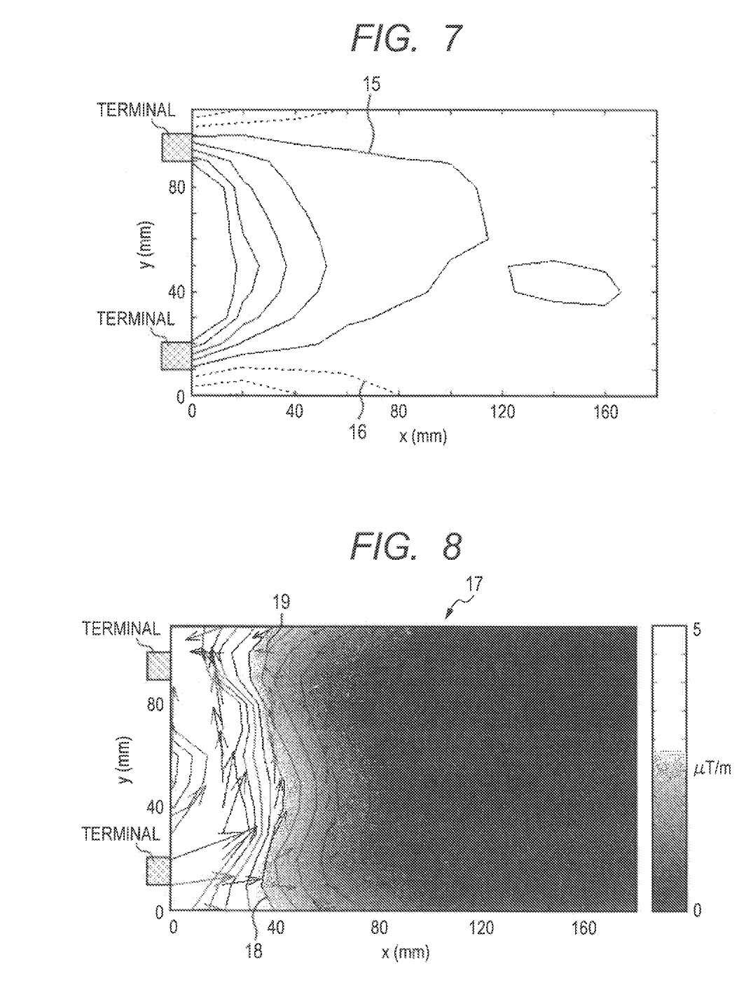

FIG. 7 illustrates magnetic field distribution of the lithium-ion battery after 15 minutes from the start of charge. FIG. 8 illustrates an electric current distribution diagram of the lithium-ion battery calculated from the magnetic field distribution of FIG. 7. From the results of FIG. 7 and FIG. 8, it can be seen that the magnetic field distribution and the electric current distribution of the lithium-ion battery after 15 minutes from the start of charge have the same trend as the magnetic field distribution and the electric current distribution just after the start of charge.

As a result of visualization of the electric current distribution of the lithium-ion battery during charging in FIG. 6 and FIG. 8, it is shown that the electric current intensity of the terminal side (left side) is high. Generally, in a structure of a laminated lithium-ion battery, collectors to which an active material (a positive electrode or a negative electrode) is applied are laminated and the laminated collector is connected at the terminal part. Therefore, electrons in the lithium-ion battery are conducted from the metal collector to the terminal part. Consequently, high electric current at the terminal side obtained by this embodiment is considered to reflect electrons collected at the terminal side by the metal collector.

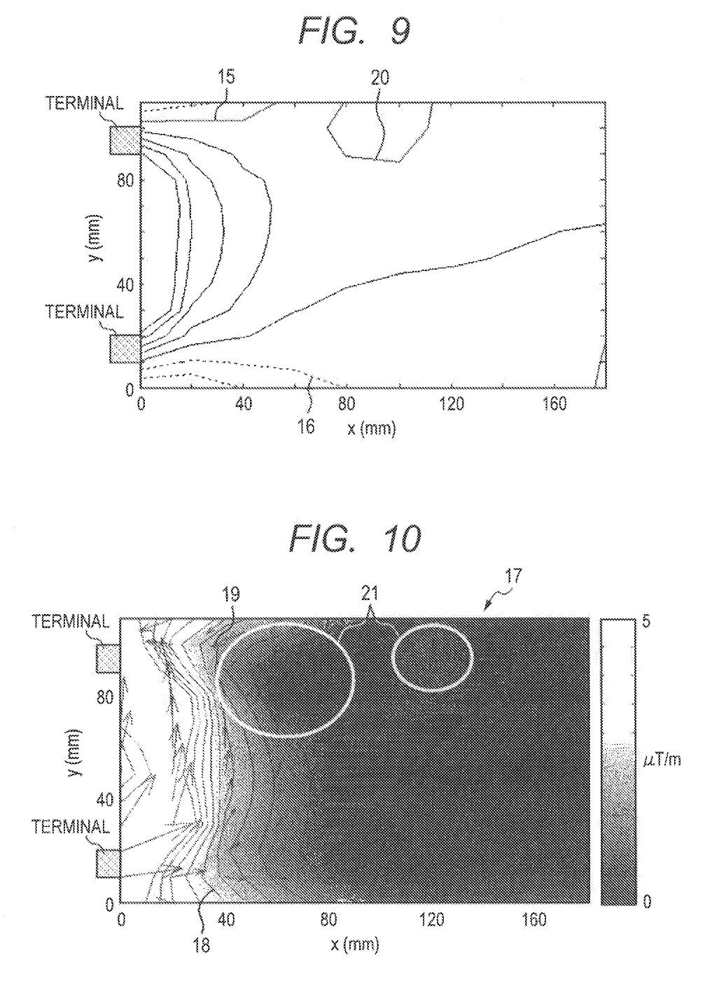

In order to verify the effect of removing the magnetic noise, a magnetic field distribution diagram and an electric current distribution diagram just after the start of charge when the analysis process 204-1 is not performed are illustrated in FIG. 9 and FIG. 10. From the magnetic field distribution in FIG. 9, it can be seen that the output of the MR sensor is not saturated by virtue of canceling the magnetic noise with the cancel coil 8 in the measurement process 102, and a continuous magnetic field distribution generated from the inside of the lithium-ion battery is obtained. However, in the magnetic field distribution of FIG. 9, a positive contour line 20 is emerged in a region located above the center of the measurement region. It can be seen that strains 21 are generated in the electric current distribution by this effect.

As described above, according to this embodiment, the magnetic field distribution of the lithium-ion battery during charging can be accurately measured, and the electric current distribution in the battery can be visualized.

By using the visualized electric current distribution in a battery, a battery is analyzed by the pattern of the electric current distribution, and a battery which is an unacceptable product can be determined. Specifically, electric current distribution of a normal lithium-ion battery is previously prepared, and a pattern of electric current distribution of a measured lithium-ion battery is compared with the pattern of the normal electric current distribution. When a degree of consistency of the electric current distribution patterns is lower than the rated value, the battery is determined as an unacceptable product.

### Second Embodiment of Method

In the second embodiment, environment noise of a magnetic signal from a lithium-ion battery recorded when discharging is removed by using a magnetic signal recorded before a start of discharge (a correction-magnetic field signal) and electric current distribution in the battery is accurately displayed.

A flow chart of the processes of the analysis procedure in this embodiment is illustrated in FIG. 4B. When the procedure is started (201), firstly, with ambient magnetic noise cancelled by each cancel coil, an average magnetic signal for correction is calculated for each magnetic sensor 2 from a magnetic signal recorded before discharge (a correction-magnetic field signal) (202). Next, for each magnetic sensor, an average magnetic signal for discharging is calculated (203-2), and a difference is calculated by subtracting the average magnetic signal for data correction from the average magnetic signal for discharging (204-2). Electric current distribution is then calculated and visualized (205). Since the process 202 and the process 205 are the same as the processes described in the first embodiment, description of these processes is omitted.

In the process 203-2, in order to improve an SN ratio of the magnetic signal for discharging, the average of the magnetic signal for discharging is calculated.

In the process 204-2, the difference is calculated by subtracting the average magnetic signal for data correction calculated in the process 202 from the average magnetic signal for discharging calculated in the process 203-2.

Processes of the second embodiment are performed though the procedure from the process 201 to 205 described above. Next, application of the second embodiment for a magnetic signal of the laminated lithium-ion battery and effectiveness thereof are described.

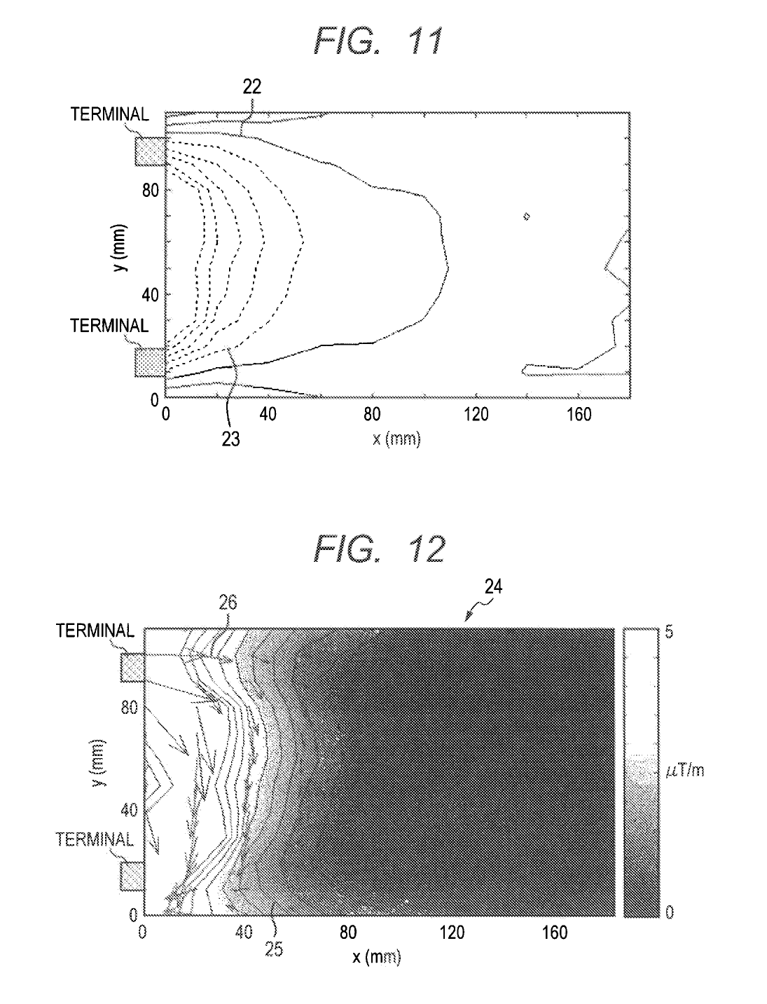

FIG. 11 is a view illustrating magnetic field distribution of the lithium-ion battery just after a start of discharge displayed by contour lines. Solid lines 22 and dotted lines 23 in FIG. 11 represent contour lines corresponding to a positive magnetic field and a negative magnetic field of the lithium-ion battery for discharging, respectively. From FIG. 11, similar to the case for charging, it can be seen that the density of the contour lines at the far left is high.

FIG. 12 illustrates an electric current distribution diagram calculated from the magnetic field distribution of FIG. 11. A gray-scale map 24 of FIG. 12 illustrates distribution of electric current intensity. A region having low electric current intensity is illustrated in black and a region having high electric current intensity is illustrated in white. Solid lines 25 in FIG. 12 are lines illustrating the electric current intensity using contour lines. Lengths of arrows 26 are corresponding to the electric current intensity and directions of the arrows 19 are corresponding to directions of electric current vectors. From FIG. 12, the electric current intensity of a terminal part at the far left is high, and the directions of the electric current vectors is left in a lower left region and is right in an upper left region. These directions are opposite to the directions for charging.

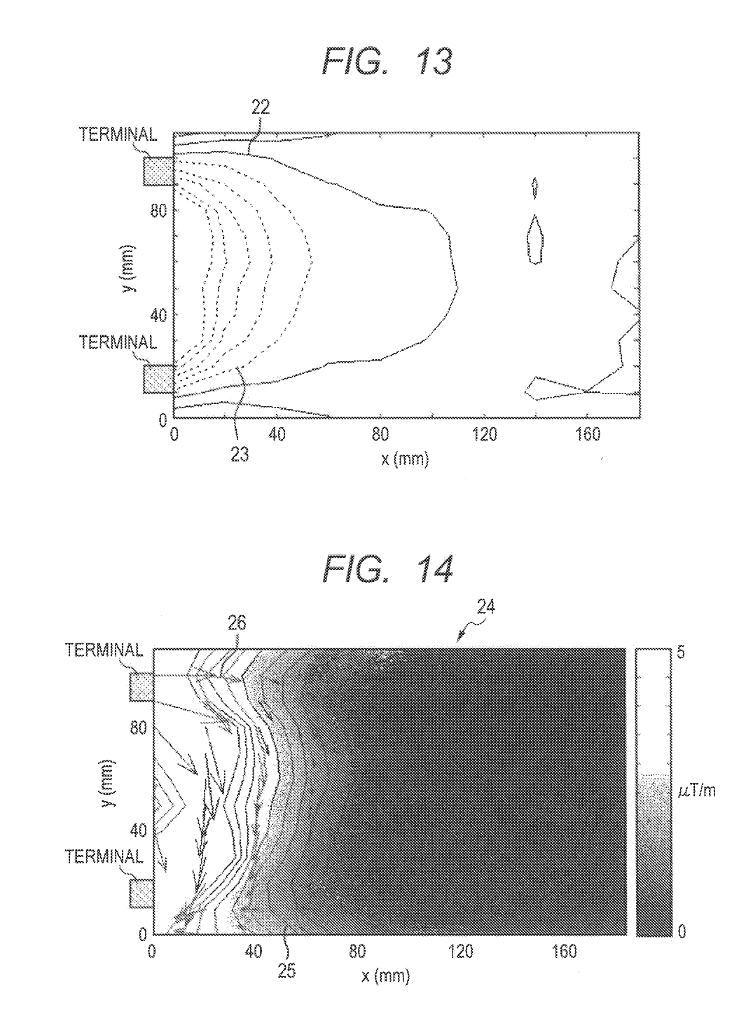

FIG. 13 illustrates magnetic field distribution of the lithium-ion battery after 20 minutes from the start of discharge. FIG. 14 illustrates an electric current distribution diagram calculated from the magnetic field distribution of FIG. 13. From the results of FIG. 13 and FIG. 14, it can be seen that the magnetic field distribution and the electric current distribution of the lithium-ion battery after 20 minutes from the start of discharge have similar trends to the magnetic field distribution and the electric current distribution just after the start of discharge.

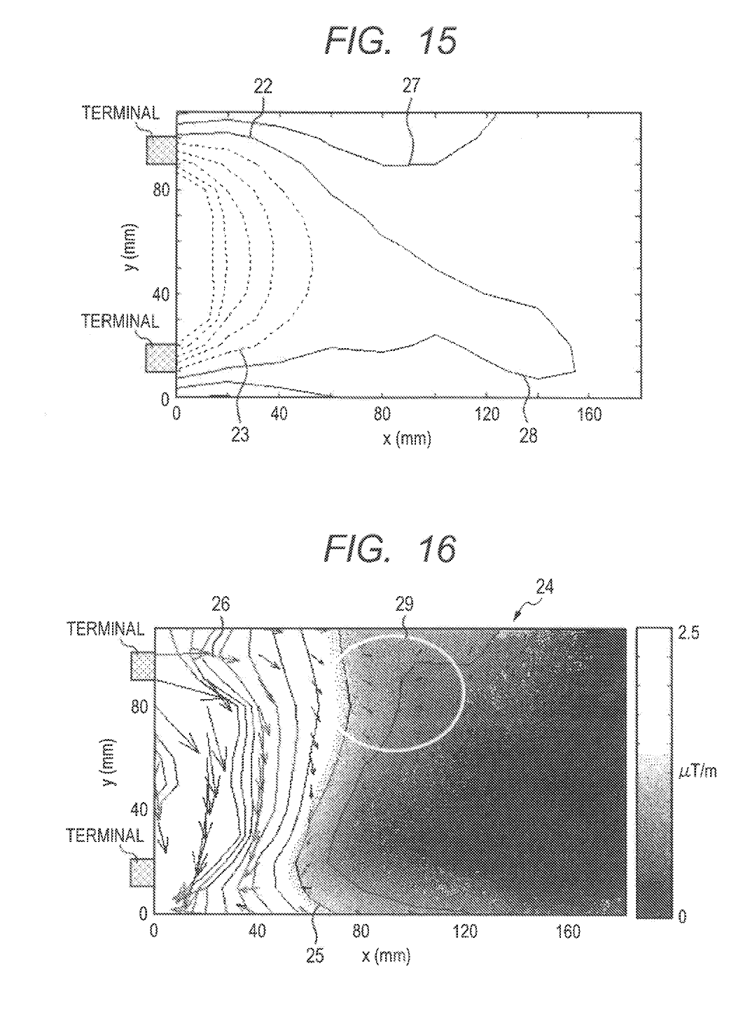

In order to verify the effect of removing the environmental noise, a magnetic field distribution diagram and an electric current distribution diagram just after the start of discharge when the analysis process 204-2 is not performed are illustrated in FIG. 15 and FIG. 16. From the magnetic field distribution in FIG. 15, similar to the case for charging, it can be seen that the output of the MR sensor is not saturated by virtue of canceling the magnetic noise with the cancel coil 8 in the measurement process 102, and a continuous magnetic field distribution generated from the inside of the lithium-ion battery is obtained. However, in the magnetic field distribution of FIG. 15, a strain 27 illustrated by a positive contour line in a region located above the center of the measurement region and a strain 28 illustrated by a positive contour line in a region located at lower right of the measurement region are emerged. It can be seen that strains 29 are generated in the electric current distribution by reflecting the effect of these strains of the contour lines.

As described above, according to this embodiment, the magnetic field distribution of the lithium-ion battery for discharging can be accurately measured, and the electric current distribution in the battery can be visualized.

### Third Embodiment of Method

In the third embodiment, a magnetic field variation is calculated using a magnetic signal at a certain measurement time during charging as a reference and electric current variation distribution in a battery is accurately displayed.

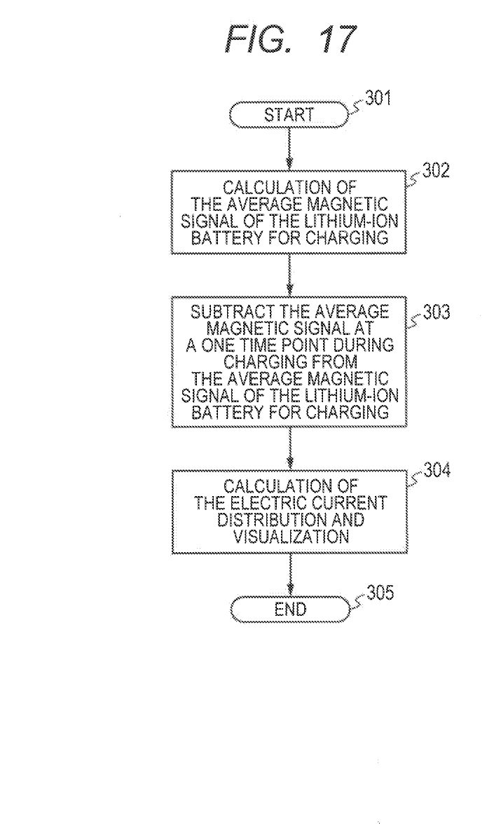

A flow chart of a procedure of analysis processes in this embodiment is illustrated in FIG. 17. When the process is started (301), firstly, with ambient magnetic noise cancelled by each cancel coil 8, an average magnetic signal for charging is calculated (302). Then, a difference is calculated by subtracting an average magnetic signal at a certain measurement time during charging from the average magnetic signal for charging (303), and electric current variation is calculated and visualized (304) . Since the process 302 is the same as the process 203-1 described in the first embodiment, description of this process is omitted.

In the process 303, the difference is calculated by subtracting the average magnetic signal at a certain measurement time during charging from the average magnetic signal for charging to calculate variation of the average magnetic signal for charging. In this embodiment, a time just after a start of charge is used as the certain measurement time during charging. However, a time just before an end of charging can also be used.

In a process 304, the method of current-arrow map was used for calculating the electric current variation from the variation of the average magnetic signal of the lithium-ion battery for charging. Each of an x component (I_{x′, i}) and a y component (I_{y′, i}) of an electric current variation vector (Iᵢ′) at an i-th position (i=1, 2, . . . , 120) obtained from the method of current-arrow map is derived from the following formulae using a variation of a magnetic field in a z direction B_{z′, i}).

I_{x′, i}=dB_{z′, i}/dy Formula (6)

I_{y′, i}=−dB_{z′, i}/dx Formula (7)

A size of the electric current variation vector (|Iᵢ′) is calculated by the following formula.

|Iᵢ′|=√((I_{x′, i})²+(I_{y′, i})²) Formula (8)

When a magnetic field in the x direction (Bₓ) and a magnetic field in the y direction (B_{y}) are measured, each of the x component (I_{x′, i}) and the y component (I_{y′, i}) of the electric current vector (Iᵢ′) at the i-th position obtained from the method of current-arrow map is derived from the following formulae using a variation of a magnetic field in an x direction B_{x′, i} and a variation of a magnetic field in a y direction B_{y′, i}.

I_{x′, i}=B_{y′, i} Formula (9)

I_{y′, i}=−B_{x′, i} Formula (10)

A size of the electric current variation vector (|Iᵢ′|) is calculated in a similar manner to Formula (8).

Processes of the third embodiment are performed though the procedure from the process 301 to 305 described above. Next, application of the third embodiment for a magnetic signal of the laminated lithium-ion battery, and effectiveness thereof are described.

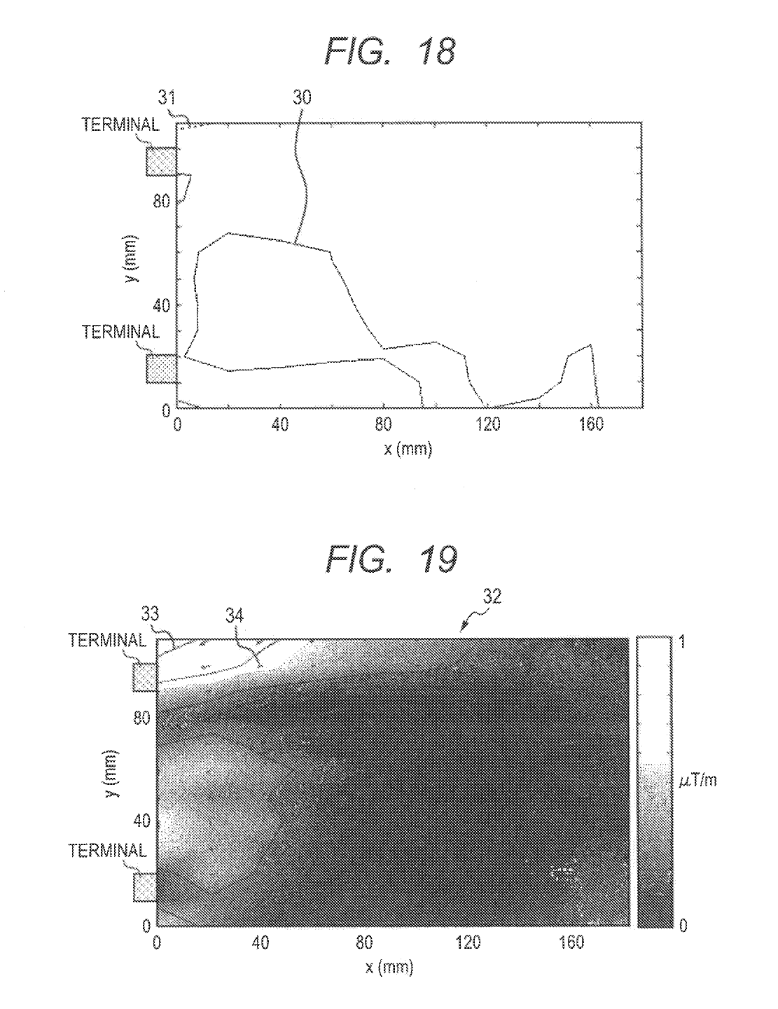

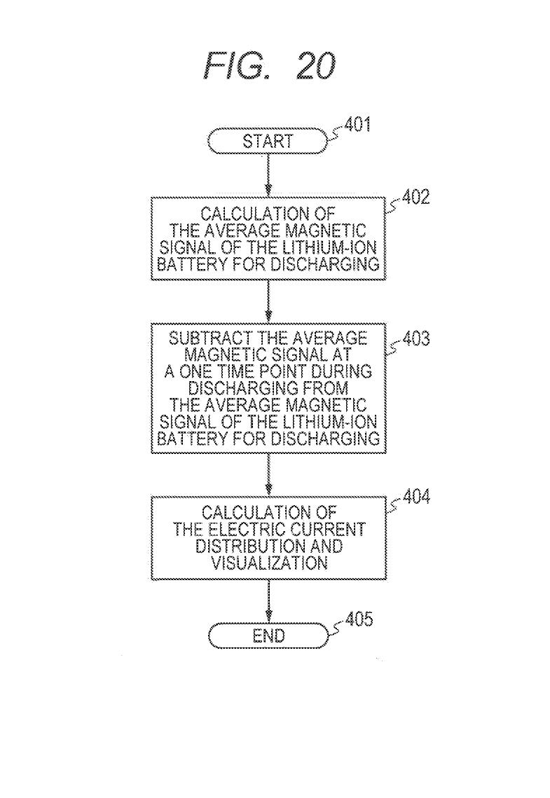

FIG. 18 is a view illustrating magnetic field variation of the lithium-ion battery after 15 minutes from the start of charge displayed by contour lines, when the magnetic field of the lithium-ion battery just after the start of charge is used as the reference. Solid lines 30 and dotted lines 31 in FIG. 18 represent contour lines corresponding to a positive magnetic field variation and a negative magnetic field variation of the lithium-ion battery for charging, respectively. From FIG. 18, it can be seen that the density of the contour lines is low, and the magnetic field after 15 minutes from the start of charge is not significantly changed relative to the magnetic field just after the start of charge.

FIG. 19 illustrates electric current variation distribution calculated from the magnetic field variation of FIG. 18. A gray-scale map 32 of FIG. 19 illustrates a variation of electric current intensity. A region having low change in the electric current intensity is illustrated in black and a region having high time change in the electric current intensity is illustrated in white. Solid lines 33 in FIG. 19 are lines illustrating variation of electric current intensity using contour lines. Lengths of arrows 34 are corresponding to the variation of the electric current intensity and directions of the arrows are corresponding to directions of change in electric current vectors. From FIG. 19, it can be seen that the change in the electric current intensity is low, and the electric current after 15 minutes from the start of charge is not significantly changed relative to the magnetic field just after the start of charge.

Here, calculating the magnetic field variation using a magnetic signal at a certain measurement time during charging as a reference has an effect for reducing magnetic noise. For example, when the same magnetic noise is mixed during charging, the magnetic noise can be removed by calculating a difference by subtracting a magnetic field at a certain measurement time from the magnetic field for charging.

As described above, according, to this embodiment, the magnetic field variation of the lithium-ion battery for charging can be accurately measured, and the electric current variation distribution in the battery can be visualized.

### Fourth Embodiment of Method

In the fourth embodiment, a magnetic field variation is calculated using a magnetic signal at a certain measurement time during discharging as a reference and electric current variation distribution in a battery is accurately displayed.

A flow chart of a procedure of analysis processes in this embodiment is illustrated in FIG. 17. When the process is started (401), firstly, an average magnetic signal for discharging is calculated (402). Subsequently, a difference is calculated by subtracting an average magnetic signal at a certain measurement time during discharging from the average magnetic signal for discharging (403), and electric current variation distribution is calculated and visualized (404). Since the process 402 is the same as the process 203-1 described in the first embodiment, description of this process is omitted. In addition, since the process 404 is the same as the process 304 described in the third embodiment, description of this process is omitted.

In the process 403, the difference is calculated by subtracting the average magnetic signal at a certain measurement time during discharging from the average magnetic signal for discharging to calculate variation of the average magnetic signal for discharging. In this embodiment, a time just after a start of discharge is used as a certain measurement time during discharging. However, a time just before an end of discharging can also be used.

Processes of the fourth embodiment are performed though the procedure from processes 401 to 405 described above. Next, application of the fourth embodiment to a process for a magnetic signal of the laminated lithium-ion battery and effectiveness thereof are described.

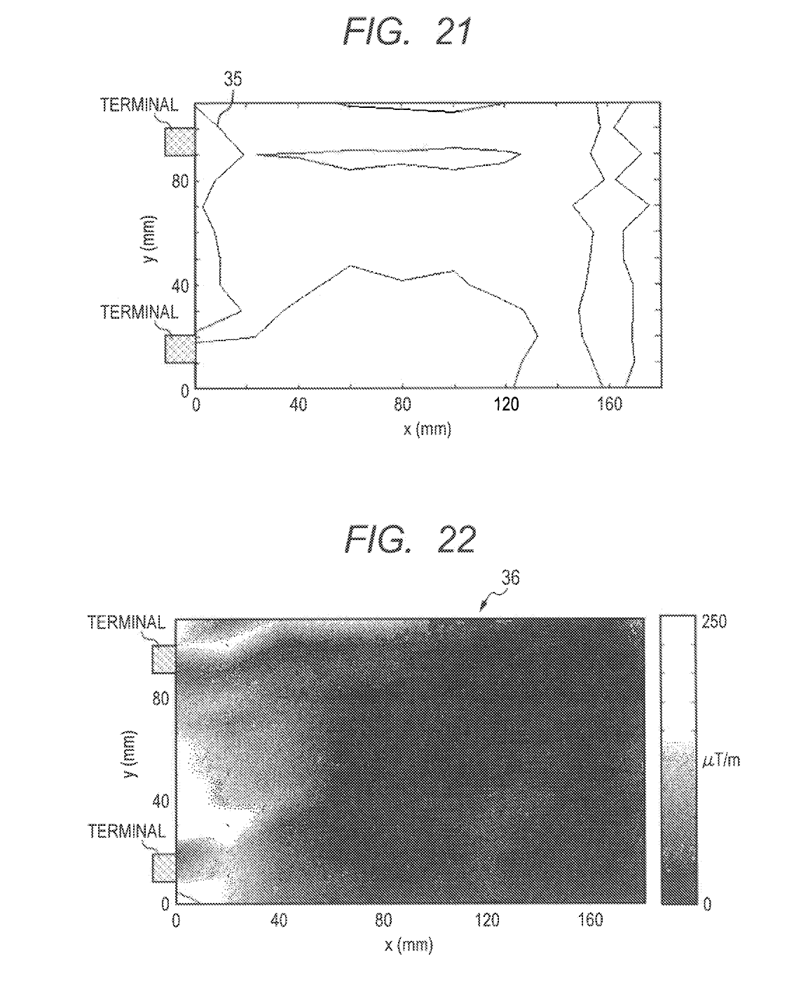

FIG. 21 is a view illustrating magnetic field variation of the lithium-ion battery after 20 minutes from the start of discharge displayed by contour lines, when the magnetic field of the lithium-ion battery just after the start of discharge is used as the standard. Solid lines 35 in FIG. 21 represent positive magnetic field variation of the lithium-ion battery for discharging. From FIG. 21, it can be seen that the density of the contour lines is low, and the magnetic field after 20minutes from the start of discharge is not significantly changed relative to the magnetic field just after the start of discharge.

FIG. 22 illustrates electric current variation distribution calculated from the magnetic field variation of FIG. 21. A gray-scale map 36 of FIG. 22 illustrates a variation of electric current intensity. A region having low change in the electric current intensity is illustrated in black and a region having high change in the electric current intensity is illustrated in white. From FIG. 22, it can be seen that the variation of the electric current intensity is low, and the electric current after 20 minutes from the start of discharge is not significantly changed relative to the electric current just after the start of discharge.

Here, calculating the magnetic field variation using a magnetic signal at a certain measurement time during discharging as a reference also has an effect for reducing magnetic noise. For example, when the same magnetic noise is mixed during discharging, magnetic noise can also be removed by calculating a difference by subtracting a magnetic field at a certain measurement time from the magnetic field for discharging.

As described above, according to this embodiment, the magnetic field variation of the lithium-ion battery for discharging can be accurately measured, and the electric current variation distribution in the battery can be visualized. Charging or discharging described in the above-described first to fourth embodiments is performed by applying direct electric current to the lithium-ion battery. However, all embodiments of the present invention can also be achieved by using pulse electric current in which an electric current value fluctuates like pulses within a predetermined period of time, alternating voltage, and the like.

Incidentally, battery characteristics of the lithium-ion battery can be grasped by calculating electric current distribution at the time of applying direct voltage or electric current, pulse voltage or electric current, and alternating voltage or electric current.

### Further Embodiments of Measurement System

A further embodiment of the measurement system includes by a unit in which several magnetic sensors of the previously described magnetic measurement system are disposed. A measurement region can be increased or decreased in increments of the unit.

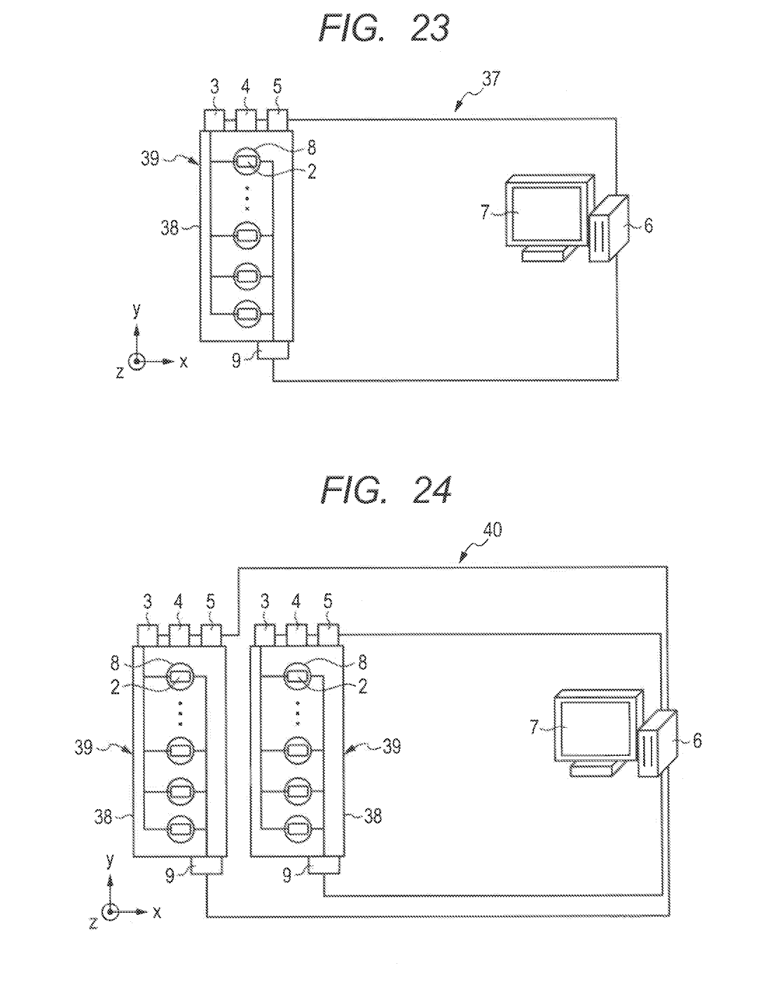

FIG. 23 is a schematic view illustrating a magnetic measurement system 37 of this embodiment constituted by a unit in which several magnetic sensors are disposed. The constituents are the same as the constituents in the system of FIG. 1. In this embodiment, the system includes a plurality of magnetic sensors 2 for measuring a magnetic signal B_{z} in a direction perpendicular to the electrode surface of the lithium-ion battery (a z direction), a driving circuit 3, an amplifier filter unit 4, an A/D converter 5, a cancel coil 8, and a D/A converter 9 being disposed on a substrate 38. One of these substrates is the unit 39 in the measurement region of the magnetic measurement system. By increasing the number of the units, the measurement regions are easily increased. In addition to the components on the substrate 38, a controlling and computing device 6 for collecting output signals from the A/D converter 5 as data, performing the analysis process of the collected magnetic field data, and controlling each part of the magnetic measurement system 37 and a display device 7 for displaying the analysis results obtained by performing the analysis process by the controlling and computing device 6 are disposed.

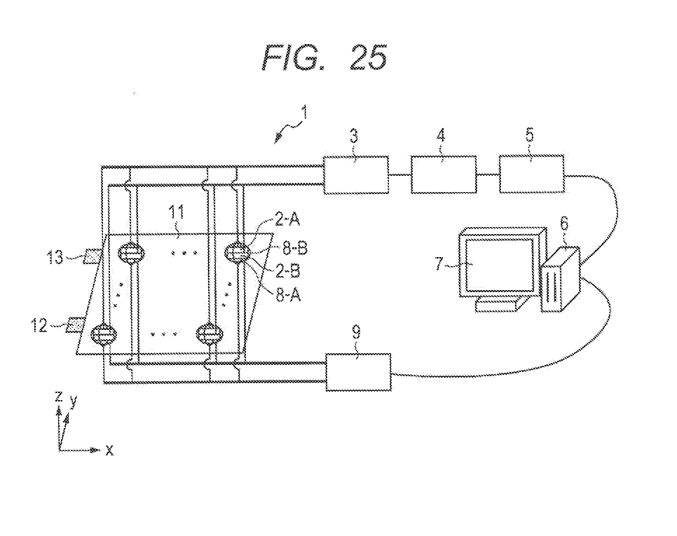

FIG. 24 is a schematic view illustrating a magnetic measurement system 40 including two of the above-described units. Two units 39 are disposed side-by-side in the x direction. The system collects the output signals from the A/D converter 5 of each unit as the data, and performs the analysis process for the collected magnetic field data as well as controls each part of the magnetic measurement system 40 by the controlling and computing device 6 disposed separately from the substrates.

As described above, the magnetic field data of the region corresponding to the size of the lithium-ion battery can be easily measured by this embodiment.

FIG. 25 is a diagram of a magnetic measurement system employing magnetic sensors for measuring a magnetic signal Bₓ in an x direction in parallel with the electrode surface of the lithium-ion battery and a magnetic signal B_{y} in a y direction perpendicular to the x direction as previously mentioned. In particular, the system includes magnetic sensors 2-A for measuring magnetic signal Bₓ surrounded by respective cancel coils 8-A, and magnetic sensors 2-B for measuring magnetic signal B_{y} surrounded by respective cancel coils 8-B. Cancel coils 8-A and 8-B are disposed so as to generate a magnetic field for cancelling the magnetic noise in the x direction and a magnetic field for cancelling the magnetic noise in the y direction, respectively. Each set of sensors and cancel coils is operated as previously described to accurately measure the respective magnetic components Bₓ and B_{y}.

What is claimed is:

1. A magnetic measurement system for measuring a magnetic field generated from a lithium-ion battery, comprising:
an electric applying portion which applies at least one of electric current and voltage through terminals of the lithium-ion battery;
a magnetic sensor which measures the magnetic field generated from the lithium-ion battery as a result of the applying by the electric applying portion;
a cancel coil which is disposed so as to surround the magnetic sensor and cancels magnetic noise detected by the magnetic sensor;
a recording portion which records a magnetic field detected by the magnetic sensor when no electric current and no electric voltage is applied to terminals of the lithium-ion battery as a correction-magnetic field;
a differential process portion which calculates a difference between a magnetic field generated from the lithium-ion battery when the at least one of the electric current and voltage is applied and the correction-magnetic field recorded by the recording portion; and
an electric current distribution calculation portion which calculates electric current distribution in the lithium-ion battery based on the difference calculated by the differential process portion.

2. The magnetic measurement system according to claim 1,
wherein the system comprises multiple magnetic sensors;
wherein the multiple magnetic sensors are disposed in parallel with a surface of one electrode side of the lithium-ion battery substantially across the entire one electrode; and
wherein the system comprises the same number of the cancel coils as the number of the multiple magnetic sensors and the cancel coils are disposed so as to surround each of the multiple magnetic sensors, respectively.

3. The magnetic measurement system according to claim 2,
wherein the multiple magnetic sensors are disposed so as to measure a magnetic field in a z direction (B_{z}) perpendicular to the surface of the one electrode; and
wherein the electric current distribution calculation portion calculates electric current in an x direction (Iₓ) and electric current in a y direction (I_{y}) in parallel with the surface of the one electrode based on the measured magnetic field in the z direction (B_{z}) from the formulae of Iₓ=dB_{z}/dy and I_{y}=−dB_{z}/dx.

4. The magnetic measurement system according to claim 2,
wherein the multiple magnetic sensors are disposed so as to measure a magnetic field in an x direction (Bₓ) in parallel with the surface of the one electrode and a magnetic field in a y direction (B_{y}) in parallel with the surface of the one electrode; and
wherein the electric current distribution calculation portion calculates electric current in the x direction (Iₓ) and electric current in the y direction (I_{y}) in parallel with the surface of the one electrode from the formulae of Iₓ=B_{y} and I_{y}=−Bₓ.

5. The magnetic measurement system according to claim 3,
wherein the electric applying portion applies at least one of direct electric current and direct voltage to the terminals of the lithium-ion battery.

6. The magnetic measurement system according to claim 3,
wherein the electric applying portion applies at least one of pulsed electric current and pulsed electric voltage to the terminals of the lithium-ion battery.

7. The magnetic measurement system according to claim 3,
wherein the electric applying portion applies alternating voltage to the terminals of the lithium-ion battery.

8. A magnetic measurement system for measuring a magnetic field generated from a lithium-ion battery, comprising:
an electric applying portion which applies at least one of electric current and voltage to the lithium-ion battery;
a magnetic sensor which measures the magnetic field generated from the lithium-ion battery as a result of the applying by the electric applying portion;
a cancel coil which is disposed so as to surround the magnetic sensor and cancels magnetic noise detected by the magnetic sensor;
a differential process portion which calculates a difference between an average magnetic signal of a magnetic field generated during one predetermined measurement time and an average magnetic signal of a magnetic field generated at a second predetermined measurement time, when the at least one of electric current and voltage is applied to terminals of the lithium-ion battery by the electric applying portion; and
an electric current distribution variation calculation portion which calculates an electric current distribution variation in the lithium-ion battery based on difference calculated by the differential process portion.

9. The magnetic measurement system according to claim 8,
wherein the system comprises multiple magnetic sensors;
wherein the multiple magmatic sensors are disposed in parallel with a surface of one electrode side of the lithium-ion battery substantially across the entire one electrode; and
wherein, the system comprises the same number of the cancel coils as the number of the multiple magnetic sensors and the cancel coils are disposed so as to surround each of the multiple magnetic sensors, respectively.

10. The magnetic measurement system according to claim 9,
wherein the multiple magnetic sensors are disposed so as to measure a magnetic field in a z direction (B_{z}′) perpendicular to the surface of the one electrode; and
wherein the electric current distribution calculation portion calculates electric current in an x direction (Iₓ′) and electric current in a y direction (I_{y}′in parallel with the surface of the one electrode based on the measured magnetic field in the z direction (B_{z}′) from the formulae of Iₓ′=dB_{z}′/dy and I_{y}′=−dB_{z}′/dx.

11. The magnetic measurement system according to claim 9,
wherein the multiple magnetic sensors are disposed so as to measure a magnetic field in an x direction (Bₓ′)in parallel with the surface of the one electrode and a magnetic field in a y direction (B_{y}′) in parallel with the surface of the one electrode; and
wherein the electric current distribution calculation portion calculates electric current in the x direction (Iₓ′) and electric current in the y direction (I_{y}′) in parallel with the surface of the one electrode from the formulae of Iₓ′=B_{y}′and I_{y}′=−Bₓ′.

12. The magnetic measurement system according to claim 8,
wherein the electric applying portion applies at, least one of direct electric current and direct voltage to the terminals of the lithium-ion battery.

13. The magnetic measurement system according to claim 8,
wherein the electric applying portion applies at least one of pulsed electric current and pulsed electric voltage to the terminals of the lithium-ion battery.

14. The magnetic measurement system according to claim 8,
wherein the electric applying portion applies alternating voltage to the terminals of the lithium-ion battery.

15. The magnetic measurement system according to claim 8,
wherein the one measurement time is just after a start of applying by the electric applying portion.

16. The magnetic measurement system according to claim 8,
wherein the one measurement time is just before an end of applying by the electric applying portion.

17. A method for measuring a magnetic field generated from a lithium-ion battery using a magnetic measurement system, the method comprising:
providing an electric applying portion which applies at least one of electric current and voltage through terminals of the lithium-ion battery; a magnetic sensor which measures the magnetic field generated from the lithium-ion battery as a result of the applying by the electric applying portion; and a cancel coil which is disposed so as to surround the magnetic sensor and cancels magnetic noise detected by the magnetic sensor in the magnetic measurement system;
supplying electric current which cancels magnetic noise detected by the magnetic sensor to the cancel coil in a state of applying no electric current and no voltage to the terminals of the lithium-ion battery;
measuring a first magnetic field detected by the magnetic sensor as a correction-magnetic field after canceling the magnetic noise by the cancel coil;
applying at least one of electric current and voltage to the lithium-ion battery by the electric applying portion to measure a second magnetic field generated from the lithium-ion battery after measuring the correction-magnetic field; and
subtracting the first magnetic field from the second magnetic field and calculating an electric current distribution in the lithium-ion battery based on a result of the subtracting.

18. The method for measuring the magnetic field according to claim 17, p1 wherein the system comprises the multiple magnetic sensors;
wherein the multiple magnetic sensors are disposed in parallel with a surface of one electrode side of the lithium-ion battery substantially across the entire one electrode; and
wherein the system comprises the same number of the cancel coils as the number of the multiple magnetic sensors and the cancel coils are disposed so as to surround each of the multiple magnetic sensors, respectively.

19. The method for measuring the magnetic field according to claim 17, further comprising:
determining whether the lithium-ion battery is an acceptable product or an unacceptable product based on a comparison of the calculated electric current distribution and a predetermined electric current distribution for an acceptable product.

20. A method for measuring a magnetic field generated from a lithium-ion battery using a magnetic measurement system, the method comprising:
providing an electric applying portion which applies at least one of electric current and voltage through terminals of the lithium-ion battery; a magnetic sensor which measures the magnetic field generated from the lithium-ion battery as a result of the applying by the electric applying portion; and a cancel coil which is disposed so as to surround the magnetic sensor and cancels magnetic noise detected by the magnetic sensor in the magnetic measurement system;
applying at least one of electric current and voltage to the terminals of the lithium-ion battery by the electric applying portion to measure a magnetic field generated in the lithium-ion battery;
calculating a first average magnetic signal from the magnetic field measured at one predetermined measurement time;
calculating a second average magnetic signal from the magnetic field measured at a second predetermined measurement time;
calculating a difference between the first and second average magnetic signals; and
calculating a variation of electric current distribution of the lithium-ion battery based on the calculated difference.
